(19) United States
(12) Patent Application Publication
(10) Pub. No.: US 2012/0070947 A1
(43) Pub. Date: Mar. 22, 2012

(54) INDUCING STRESS IN FIN-FET DEVICE

(75) Inventors: Veeraraghavan S. Basker, Schenectady, NY (US); Huiming Bu, Glenmont, NY (US); Effendi Leobandung, Fishkill, NY (US); Theodorus E. Standaert, Clifton Park, NY (US); Kingsuk Maitra, Guilderland, NY (US)

(73) Assignees: GLOBALFOUNDRIES INC., Grand Cayman (KY); INTERNATIONAL BUSINESS MACHINES CORPORATION, Armonk, NY (US)

(21) Appl. No.: 12/883,255

(22) Filed: Sep. 16, 2010

(51) Int. Cl. H01L 21/336; H01L 21/263

(52) U.S. Cl. 438/197; 257/E21.409

(57) ABSTRACT

A method of forming a fin-shaped field effect transistor (fin-FET) is disclosed. In one embodiment, the method comprises: partially amorphizing a fin overlying a substrate; forming a stress layer over a portion of the partially amorphized fin; annealing to impart stress in the partially amorphized fin to form a stressed fin; removing the stress layer from over the portion of stressed fin; and forming a gate over the stressed fin after the removing of the stress layer.

### BACKGROUND OF THE INVENTION

The subject matter disclosed herein relates to solutions for inducing stress in a fin-shaped field effect transistor (fin-FET). More specifically, the subject matter disclosed herein relates to a method of forming a fin-FET structure having stress induced before the gate structure is formed.

Semiconductor device designers continually work to make semiconductor devices smaller while increasing their level of performance. One approach to increasing performance is the use of stress liners over portions of these devices. In traditional fin-FET devices, stress is applied across the device channel after the gate has been formed. Because the channel is at least partially obstructed by the gate, attempts to induce an effective amount of stress on the channel after gate formation may prove unsuccessful.

### BRIEF SUMMARY OF THE INVENTION

Solutions for inducing stress in a fin-shaped field effect transistor (fin-FET) device are disclosed. In one aspect, a method of forming a fin-shaped field effect transistor comprises: partially amorphizing a fin overlying a substrate; forming a stress layer over a portion of the partially amorphized fin; annealing to impart stress in the partially amorphized fin to form a stressed fin; removing the stress layer from over the portion of the stressed fin; and forming a gate over the stressed fin after the removing of the stress layer.

A first aspect of the invention provides a method of forming a fin-shaped field effect transistor (fin-FET), the method comprising: partially amorphizing a fin overlying a substrate; forming a stress layer over a portion of the partially amorphized fin; annealing to impart stress in the partially amorphized fin to form a stressed fin; removing the stress layer from over the portion of the stressed fin; and forming a gate over the stressed fin after the removing of the stress layer.

A second aspect of the invention provides a method of forming a fin-shaped field effect transistor (fin-FET), the method comprising: partially amorphizing a semiconductor layer overlying a substrate; forming a partially amorphized fin from the partially amorphized semiconductor layer; forming a stress layer over a part of the partially amorphized fin; annealing to impart stress in the partially amorphized fin to form a stressed fin; removing the stress layer from over the portion of the stressed fin; and forming a gate over the stressed fin after the removing of the stress layer.

A third aspect of the invention provides a method of forming a fin-shaped field effect transistor (fin-FET), the method including: partially amorphizing a semiconductor layer overlying a substrate; forming a stress layer over a part of the partially amorphized semiconductor layer; annealing the stress layer to impart stress in the partially amorphized semiconductor layer to form a stressed semiconductor layer; removing the stress layer; forming a stressed fin from the stressed semiconductor layer after the removing of the stress layer; and forming a gate over the stressed fin.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 shows a three-dimensional perspective view of a semiconductor structure undergoing a method according to an embodiment.

FIG. 2 shows a three-dimensional perspective view of a semiconductor structure undergoing a method according to an embodiment.

FIG. 3 shows a three-dimensional perspective view of a semiconductor structure undergoing a method according to an embodiment.

FIG. 4 shows a three-dimensional perspective view of a semiconductor structure undergoing a method according to an embodiment.

FIG. 5 shows a three-dimensional perspective view of a semiconductor structure undergoing a method according to an embodiment.

FIG. 6 shows a three-dimensional perspective view of a semiconductor structure undergoing a method according to an embodiment.

FIG. 7 shows a three-dimensional perspective view of a semiconductor structure undergoing a method according to an embodiment.

FIG. 8 shows a three-dimensional perspective view of a semiconductor structure undergoing a method according to a second embodiment.

FIG. 9 shows a three-dimensional perspective view of a semiconductor structure undergoing a method according to a second embodiment.

FIG. 10 shows a three-dimensional perspective view of a semiconductor structure undergoing a method according to a second embodiment.

FIG. 11 shows a three-dimensional perspective view of a semiconductor structure undergoing a method according to a third embodiment.

FIG. 12 shows a three-dimensional perspective view of a semiconductor structure undergoing a method according to a third embodiment.

FIG. 13 shows a three-dimensional perspective view of a semiconductor structure undergoing a method according to a third embodiment.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

As used herein, the term “deposition” may include any now known or later developed techniques appropriate for the material to be deposited including but are not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser-assisted deposition, thermal oxidation, thermal nitridation, spin-on methods, physical vapor deposition (PVD), atomic layer deposition (ALD), chemical oxidation, molecular beam epitaxy (MBE), plating, evaporation, etc.

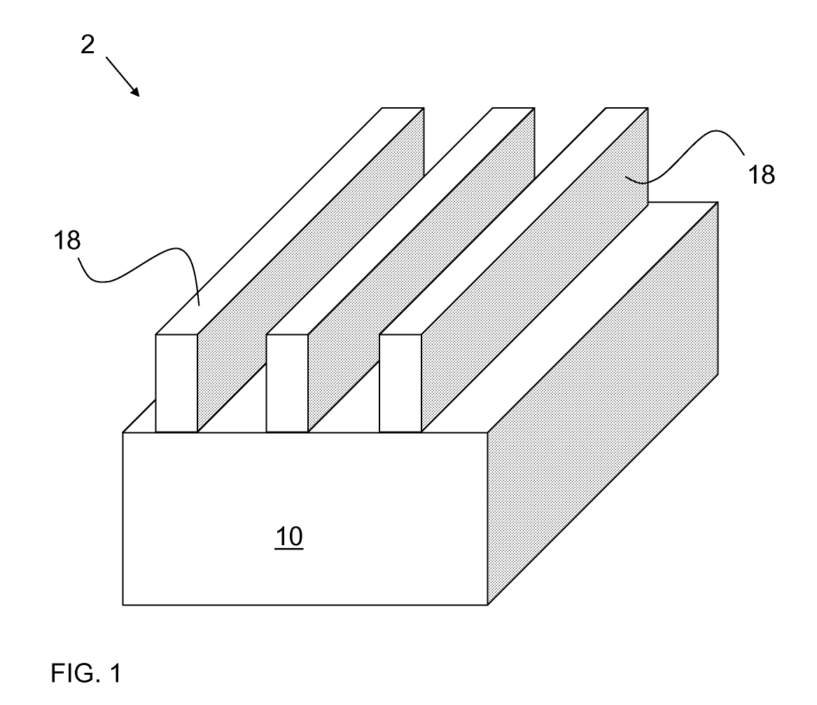

Turning to FIG. 1, a semiconductor structure 2 is shown including a substrate 10, and at least one partially amorphized fin 18 overlying the substrate 10. In one embodiment, the substrate 10 may include, e.g., a buried oxide (BOX), strained Si, SiGe, etc. Partially amorphized fin(s) 20 may include, for example, silicon (Si), strained Si, SiGe, etc. It is understood that partially amorphized fin(s) 18 may be formed in any conventional manner. For example, partially amorphized fin(s) 18 may be formed by implanting a silicon (or other conventional substrate material) layer with argon (Ar), helium (He), xenon (Xe), germanium (Ge), carbon (C), or Si. In this embodiment, fin(s) 18 have already been partially amorphized, and the specific methods of forming amorphized fin(s) 18 have accordingly been omitted from the description of semiconductor structure 2.

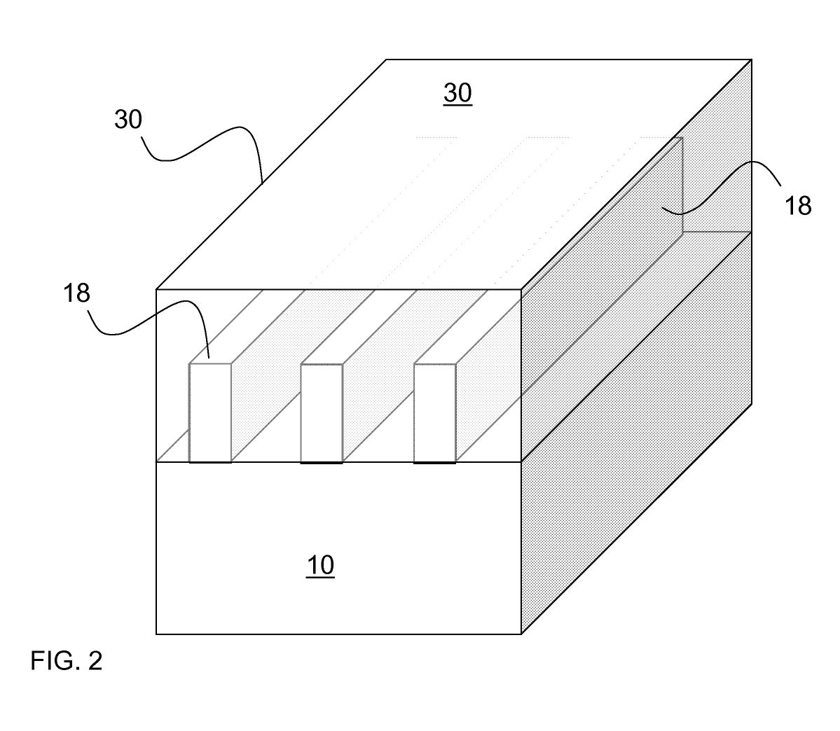

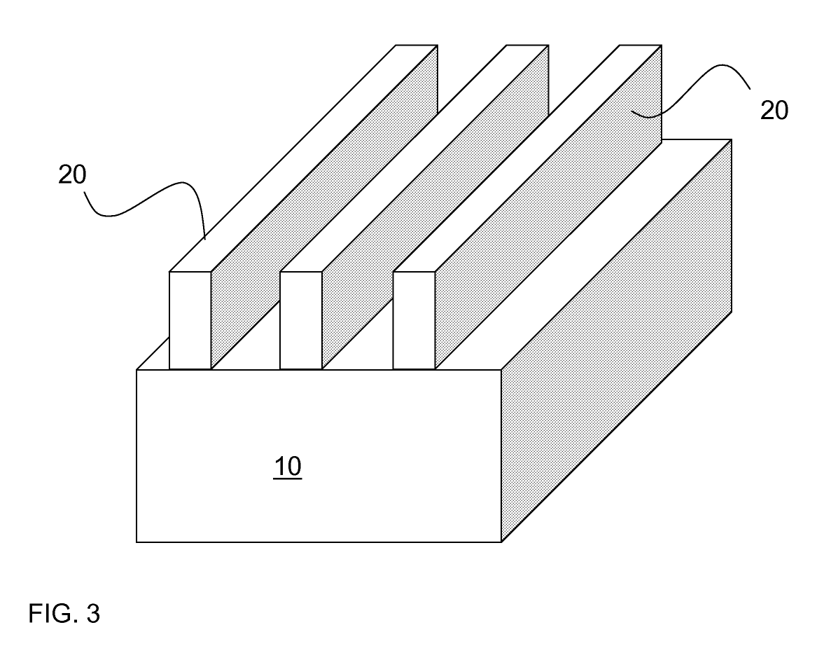

Turning to FIG. 2, the semiconductor structure of FIG. 1 is shown after depositing of a nitride stress layer 30 (shown partially transparently) directly over the partially amorphized fin(s) 18 and the underlying substrate 10. In one embodiment, nitride stress layer 30 may substantially cover partially amorphized fins 18. Nitride stress layer 30 may include, for example, a tensile stress nitride or a compressive stress nitride, as are known in the art. Nitride stress layer 30 may further include distinct stress layers (e.g., tensile and compressive), as is further described herein. However, in the depiction of FIG. 2, nitride stress layer 30 includes one of a tensile stress nitride or a compressive stress nitride. Nitride stress layer 30 may be formed by any deposition technique described herein or conventionally known. For example, nitride stress layer 30 may be deposited by CVD. Following deposition of nitride stress layer 30, annealing may be performed to impart stress from nitride stress layer 30 into partially amorphized fins 18 and the underlying substrate 10. As is known in the art, annealing may include heating materials (e.g., nitride stress layer 30, partially amorphized fins, and substrate 10) to above their re-crystallization temperature, maintaining that temperature for a period, and then allowing the altered materials to cool. As is known in the art, annealing the semiconductor structure while nitride stress layer 30 overlies partially amorphized fins 18 and substrate 10 may allow the stress from nitride stress layer 30 to “memorize” in the partially amorphized fins 18 and substrate 10. This annealing may also substantially restore the crystallinity (crystalline structure) of partially amorphized fins 18, and aid in forming stressed fins 20 (FIG. 3). This “memorizing” means the stress may remain in the stressed fins 20 and substrate 10 after subsequently removing nitride stress layer 30.

Turning to FIG. 3, the semiconductor structure of FIG. 2 is shown after removal of the nitride stress layer 30 (after annealing). Nitride stress layer 30 may be removed, for example, using a conventional hot phosphorous bath. Alternatively, nitride stress layer 30 may be removed by conventional masking and etching techniques. Although not visibly apparent, the semiconductor structure of FIG. 3 differs from semiconductor structure 2 of FIG. 1. That is, the semiconductor structure of FIG. 3 includes an imparted stress (provided by annealing with nitride stress layer 30) absent in semiconductor structure 2 of FIG. 1. This stress may be imparted in both stressed fins 20 and the stressed substrate 10

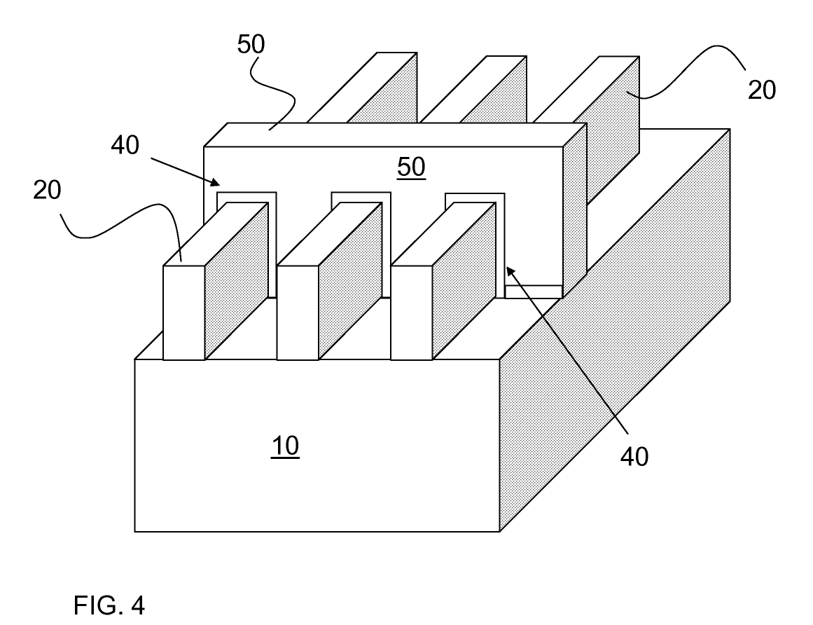

Turning to FIG. 4, the semiconductor structure of FIG. 3 is shown, further including a metal high-dielectric constant (MHK) layer 40 formed over the stressed fins 20 (shown selectively formed over each stressed fin 20). As is known in the art, MHK layer 40 may include any metal having a dielectric constant value (k) greater than approximately 18, and may be formed over stressed fins 20 by, e.g., selective deposition, masking and/or etching. In any case, MHK layer 40 may be formed using conventional techniques and include a conventional high-dielectric constant material. Further shown in FIG. 4 is a gate 50 formed over the MHK layer 40 and the stressed fins 20. Gate 50 may be formed of conventional fin-shaped field effect transistor (fin-FET) gate materials, and may include, e.g., boron-doped silicon, phosphorous-doped silicon, arsenic-doped silicon, a fully silicided gate, or a full or partial metal-gate. Gate 50 may be formed using any conventional techniques such as selective deposition, masking and/or etching.

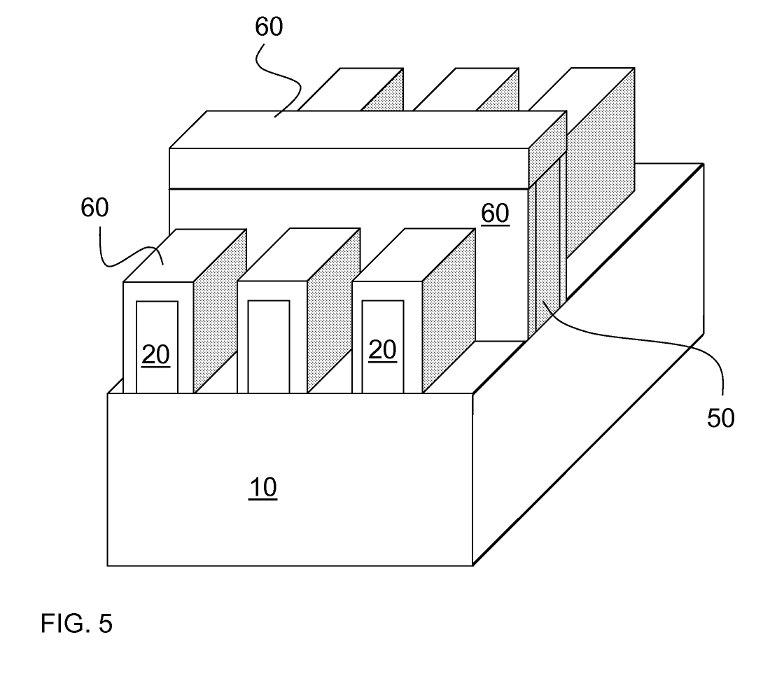

Turning to FIG. 5, the semiconductor structure of FIG. 4 is shown further including a spacer (e.g., a nitride spacer) layer 60 formed over the stressed fins 20, the exposed portions of the MHK layer 40 (not visible) and the gate 50. Spacer layer 60 may be deposited in any conventional manner, and may cover exposed portions of gate 50, MHK layer 40 and stressed fins 20.

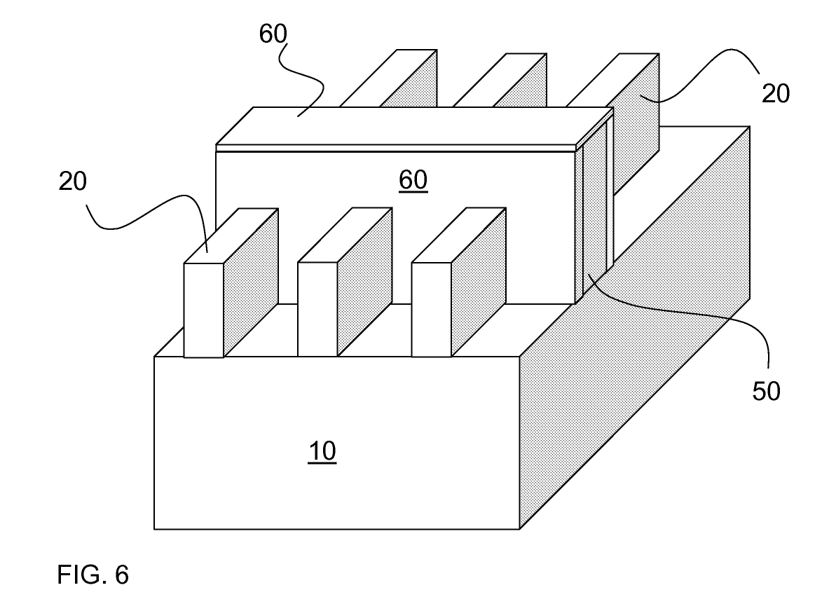

Turning to FIG. 6, the semiconductor structure of FIG. 5 is shown after selective etching of spacer layer 60. Spacer layer 60 may be selectively etched using, e.g., reactive ion etching, conventional masking and etching, etc. As shown in FIG. 6, selective etching of spacer layer 60 may expose stressed fins 20, while leaving a thinner spacer layer 60 than originally deposited overlying gate 50 and MHK layer 40 (not visible).

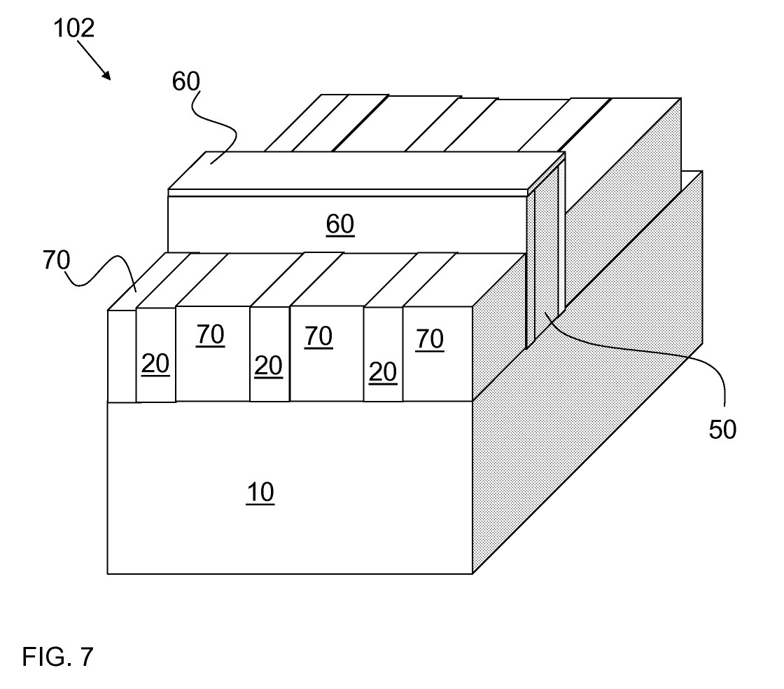

Turning to FIG. 7, the semiconductor structure of FIG. 6 is shown further including source/drain regions 70, formed between stressed fins 20. Source/drain regions 70 may be formed of any conventional source/drain material, e.g., doped silicon, doped polysilicon, SiGe, etc. In one embodiment, source/drain regions 70 may be epitaxially grown and merged with stressed fins 20. In one embodiment, source/drain regions 70 may be doped after they are epitaxially grown (e.g., via selective doping using a mask). As shown, after forming of the source/drain regions 70, a fin-FET structure 102 may be formed.

Unlike conventional fin-FET structures, fin-FET structure 102 may have increased stress across a channel region running below the gate 50. That is, in conventional fin-FET formation, stress is induced in the channel region after formation of the gate 50 (and traditionally, after formation of the source-drain regions 70). In contrast to conventional fin-FET formation, forming of fin-FET structure 102 as described herein includes partially amorphizing the fins (20) and inducing stress in those fins prior to formation of the gate 50. This may allow for increased stress in the later-formed channel region (including the portion of fins underlying MHK layer 40 and gate 50). As is known in the art, this increased stress in the channel region may help improve the performance of fin-FET 102.

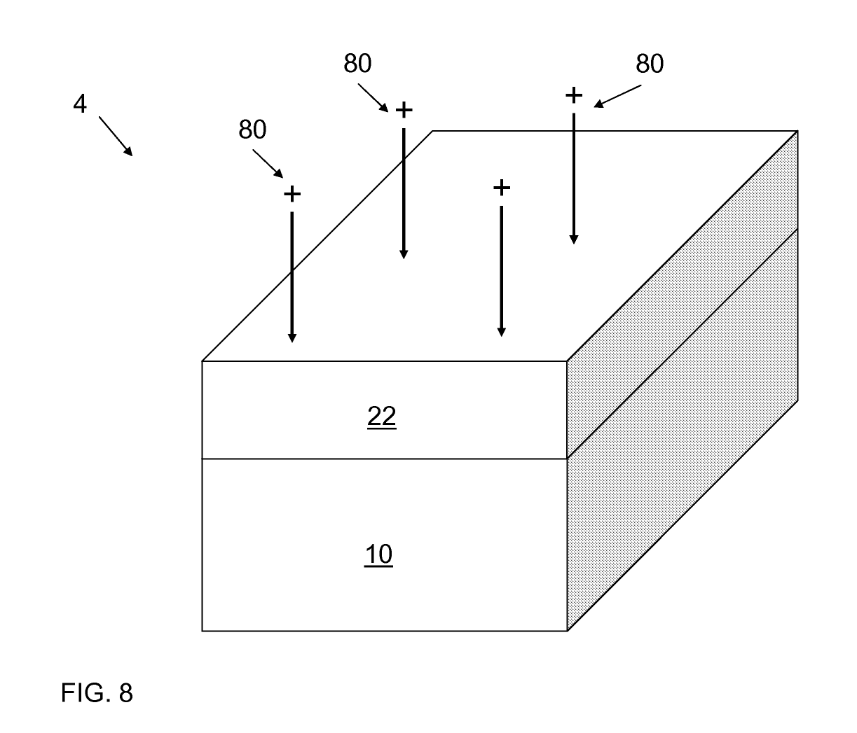

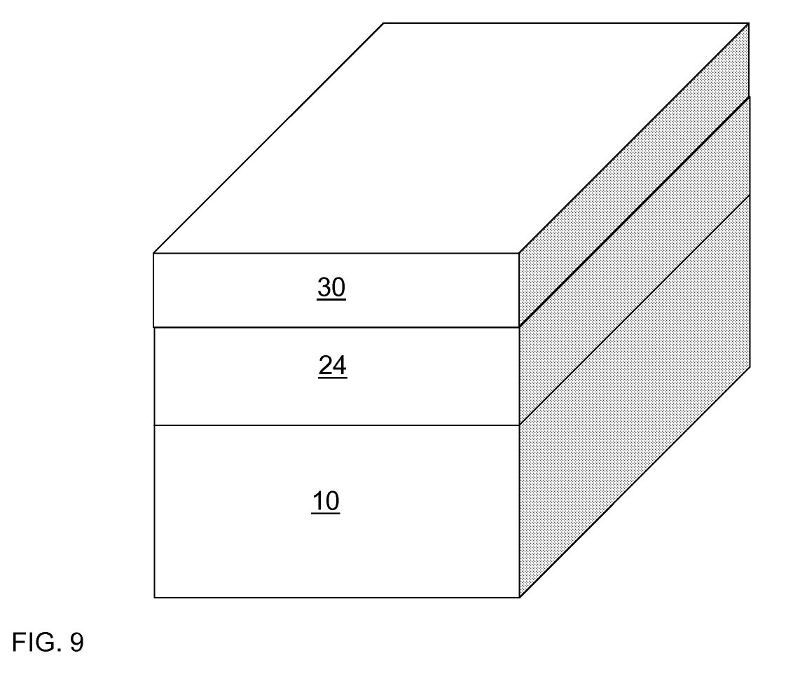

Turning to FIGS. 8-10, an alternative embodiment of forming a fin-FET having improved stress along its channel region is shown. FIG. 8 shows a semiconductor structure 4 including a substrate 10 and a precursor fin layer 22 thereover. It is understood that precursor fin layer 22 may provide the basis for at least one later formed fin (e.g., fin(s) 20 of FIGS. 1-7). Precursor fin layer 22 may include a silicon (Si), silicon dioxide (SiO₂), strained Si, SiGe, etc. and may be formed over substrate 10 using conventional methods (e.g., deposition, epitaxial growth, etc.). A method of forming a fin-FET according to this alternative embodiment may include the process of partially amorphizing precursor fin layer 22. In one embodiment, partially amorphizing of precursor fin layer 22 may be performed by implanting precursor fin layer 22 with ions 80. In one embodiment, precursor fin layer 22 may be implanted with argon (Ar), xenon (Xe), helium (He), germanium (Ge), carbon (C), or Si ions 80. Ion implanting may be performed on precursor fin layer 22 using any conventional methods. In any case, partially amorphizing precursor fin layer 22 modifies the precursor fin layer 22 to form partially amorphized precursor fin layer 24 (FIG. 9).

Turning to FIG. 9, after partially amorphizing precursor fin layer 22 to form partially amorphized precursor fin layer 24, a stress layer 30 may be formed over partially amorphized precursor fin layer 24. Stress layer 30 may be formed in a substantially similar manner to similarly numbered stress layer 30, shown and described with reference to FIG. 2. Stress layer 30 may include a nitride. In one embodiment, the nitride may be either a tensile stress nitride or a compressive stress nitride. In another embodiment (not shown), stress layer 30 may include a dual-stress liner. The dual-stress liner may be formed via deposition of a first tensile (or compressive) stress layer over a portion of partially amorphized precursor fin layer 24, followed by masking of the first tensile (or compressive) stress layer and depositing of a second stress layer (of opposite stress type than first stress layer) over a second, distinct portion of partially amorphized precursor fin layer 24. It is understood that in this embodiment, the second stress layer may be formed only on the exposed portion of amoprhized precursor fin layer 24. However, in another embodiment, second stress layer may be formed over both the exposed portion of amorphized precursor fin layer 24 and the first stress layer. While this may decrease the stress imparted by the first stress layer, it may also reduce the number of processing steps in forming a fin-FET structure.

In any case, returning to FIG. 9, after forming of stress layer 30, the semiconductor structure may be annealed, as described with reference to FIG. 2. This annealing may impart (or “memorize) stress from stress layer 30 into the underlying partially amorphized precursor fin layer 24, forming a stressed precursor fin layer (not shown). As described with reference to FIGS. 2-3, annealing to memorize stress may substantially restore the crystallinity (crystalline structure) of partially amorphized precursor fin layer 24, forming the stressed precursor fin layer. As described herein, this imparted stress may provide for improved performance of a later formed fin-FET including fins formed from the stressed precursor fin layer.

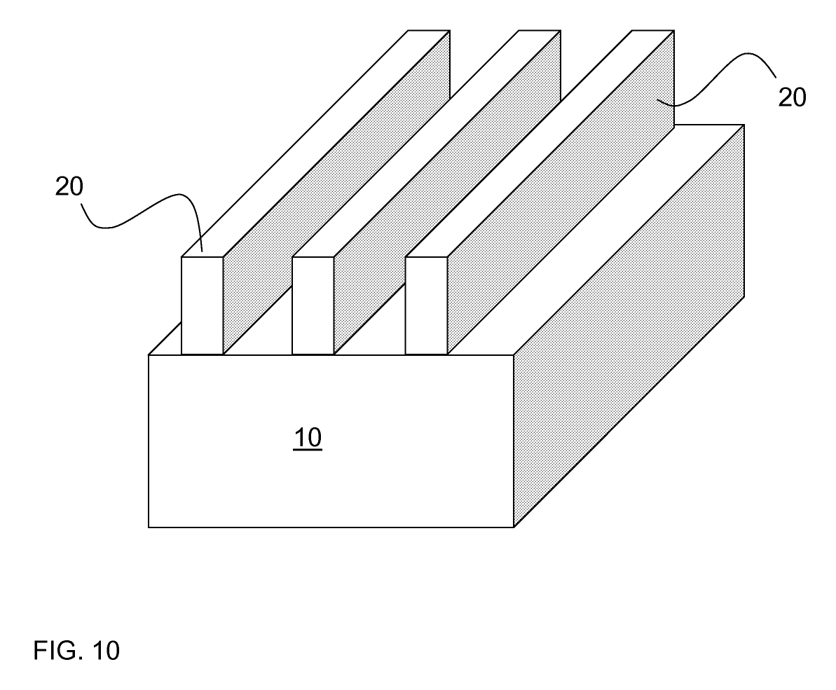

Turning to FIG. 10, a semiconductor structure 2 having a substantially similar composition as the semiconductor structure of FIG. 3 is shown. With reference to FIGS. 9-10, after annealing to impart stress in partially amorphized precursor fin layer 24 (forming the stressed precursor fin layer, as described with reference to FIG. 9), stress layer 30 (FIG. 9) may be removed. In one embodiment, as described with reference to FIG. 3, stress layer 30 may be removed using a hot phosphorous bath. However, it is understood that stress layer 30 may alternatively be removed using any conventional methods, e.g., masking and etching. After removal of stress layer 30, stressed fins 20 may be formed from the stressed precursor fin layer. In one embodiment, stressed fins 20 may be formed by masking and selectively etching the stressed precursor fin layer to form fin-shaped structures. In another embodiment, stressed fins 20 may be formed using a sidewall image transfer (SIT) technique to create stressed fins 20 at a dense pitch. Following formation of the semiconductor structure of FIG. 10, the processes of forming the MHK layer 40, gate 50, spacer layer 60 and source/drain regions 70 of FIGS. 3-7 may be implemented to form a substantially similar structure to fin-FET structure 102. Repeated discussion of these processes has been omitted for brevity.

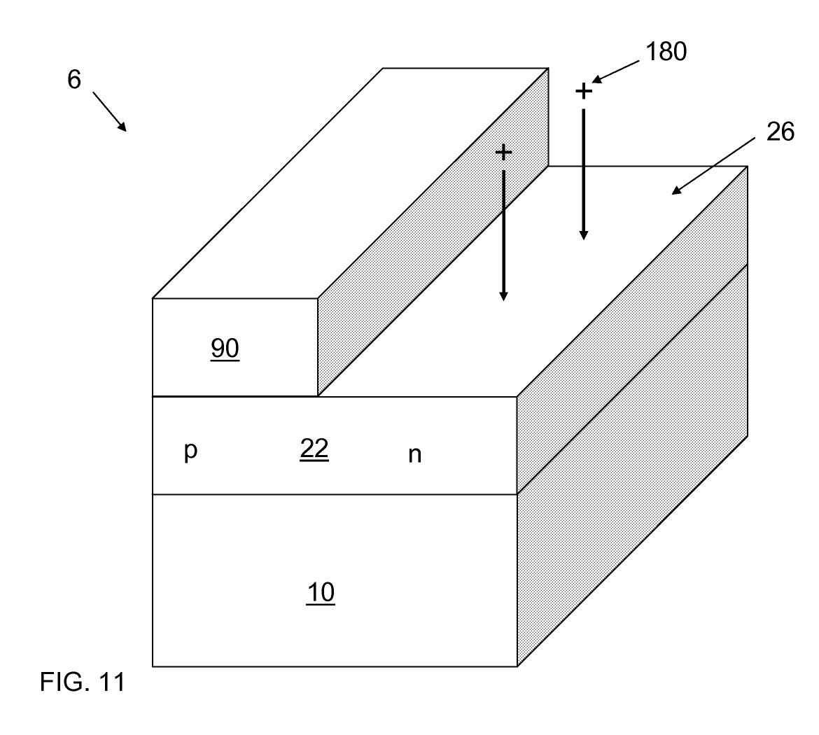

Turning to FIGS. 11-13, another alternative process of forming a fin-FET structure (similar to fin-FET structure 102) is illustrated. FIG. 11 shows a semiconductor structure 6 including a substrate 10 and a precursor fin layer 22 thereover. Substrate 10 and precursor fin layer 22 may be substantially similar to substrate 10 and precursor fin layer 22 shown and described with reference to FIG. 8, and as such, are not described further. Also included in semiconductor structure 6 is a mask layer 90, which may be deposited or otherwise conventionally formed over precursor fin layer 22. Mask layer 90 may provide for exposure of only a portion 26 of precursor fin layer 22 (e.g., during a subsequent amorphizing step). Mask layer 90 may be formed of any conventional mask material, e.g., a material capable of preventing ions from passing therethrough during an ion implantation process. As is further shown in FIG. 11, after forming mask layer 90 over precursor fin layer 22, exposed portion 26 of precursor fin layer 22 may be amorphized via, e.g., implanting with ions 180. In one embodiment, exposed portion 26 may later form the n-type field effect transistor (nFET) portion of a fin-FET structure. In this case, ions 180 may include, e.g., carbon (C) to enhance strain. In this embodiment, additional steps (not shown) may include: removing the mask layer 90 (e.g., via etching, dry stripping or wet stripping) after ion implanting exposed portion 26 to expose a second portion of precursor fin layer 22; forming a second mask layer over exposed portion 26 to cover exposed portion 26 (or, n-type doped portion) and keep the second portion exposed; amorphizing the second portion (e.g., via ion implanting) with a p-type dopant such as germanium (Ge) to enhance strain; and removing the second mask layer to expose the n-type doped portion.

It is understood that after ion implanting precursor fin layer 22 with n-type ions and p-type ions, respectively, precursor fin layer 22 may be effectively amorphized such that its physical composition is altered. Accordingly, precursor fin layer 22 may be transformed into a partially amorphized precursor fin layer 24, as described with reference to FIGS. 8-9.

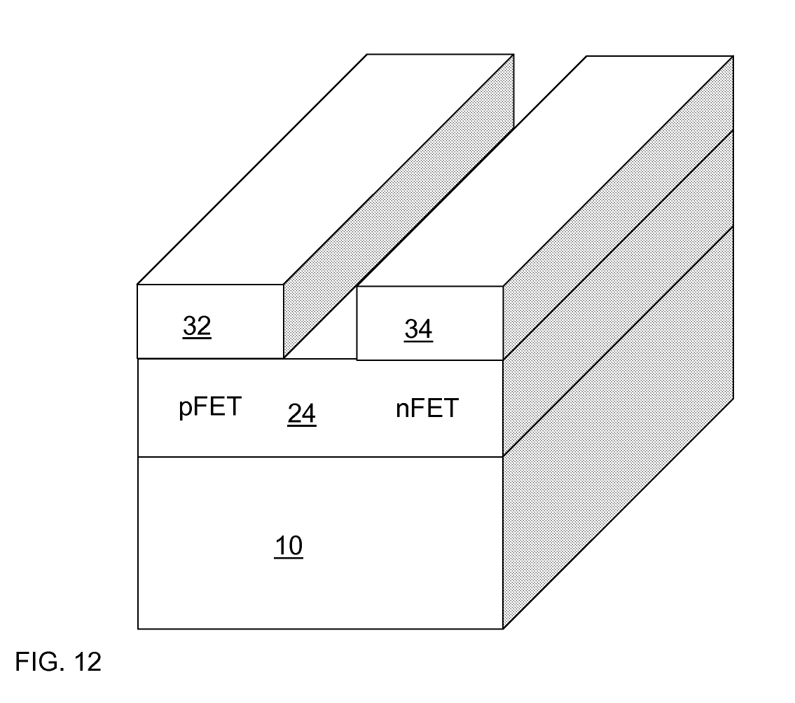

Turning to FIG. 12, after removal of the second mask layer (and ion implanting of the p-type and n-type doped regions), stress layers 32, 34 may be formed over partially amorphized precursor fin layer 24. In one embodiment, a first stress layer 32 may be formed (e.g., deposited) over pFET portion of partially amorphized precursor fin layer 24, and a second stress layer 34 may be formed (e.g., deposited) over nFET portion of partially amorphized precursor fin layer 24. First stress layer 32 over the pFET portion may include, for example, a compressive stress layer (e.g., a compressive stress nitride). As is known in the art, compressive stress layers may be used to improve the performance of an underlying the pFET portion when that compressive stress is effectively imparted into the underlying the pFET portion. Second stress layer 34 over the nFET portion may include a tensile stress layer (e.g., a tensile stress nitride). As is known in the art, tensile stress layers may be used to improve the performance of an underlying the nFET portion when that tensile stress is effectively imparted into the underlying the nFET portion. First stress layer 32 and second stress layer 34 may be formed over partially amorphized precursor fin layer 24 in any order. Further, in one embodiment, forming of first stress layer 32 and second stress layer 34 may be formed via the following process: masking a first portion of partially amorphized precursor fin layer 24; depositing a stress layer (e.g., first or second stress layers 32, 34) over a second, unmasked portion of partially amorphized precursor fin layer 24; masking over the first deposited stress layer (e.g., via deposition); removing the mask (e.g., via etching) over the first portion of partially amorphized precursor fin layer 24; and forming (e.g., via deposition) a second stress layer (e.g., the other of the first or second stress layers 32, 34) over the first portion of partially amorphized precursor fin layer 24. It is understood that first stress layer 32 or second stress layer 34 may be masked first in the above-described process.

After forming of first stress layer 32 and second stress layer 34 over the pFET portion and nFET portion, respectively, of partially amorphized precursor fin layer 24, the semiconductor structure may be annealed to impart (or, “memorize”) stress in the underlying partially amorphized precursor fin layer 24, to form a stressed precursor fin layer (not shown). As described with reference to FIGS. 2-3 and 9-10, annealing may impart stress in the underlying partially amorphized precursor fin layer 24, thereby substantially restoring the crystallinity (crystalline structure) of partially amorphized precursor fin layer 24, forming the stressed precursor fin layer. After the annealing, first stress layer 32 and second stress layer 34 may be removed (e.g., via a hot phosphorous bath) as described with respect to FIGS. 2-3 and 9-10. First stress layer 32 and second stress layer 34 may be removed simultaneously, or in separate steps.

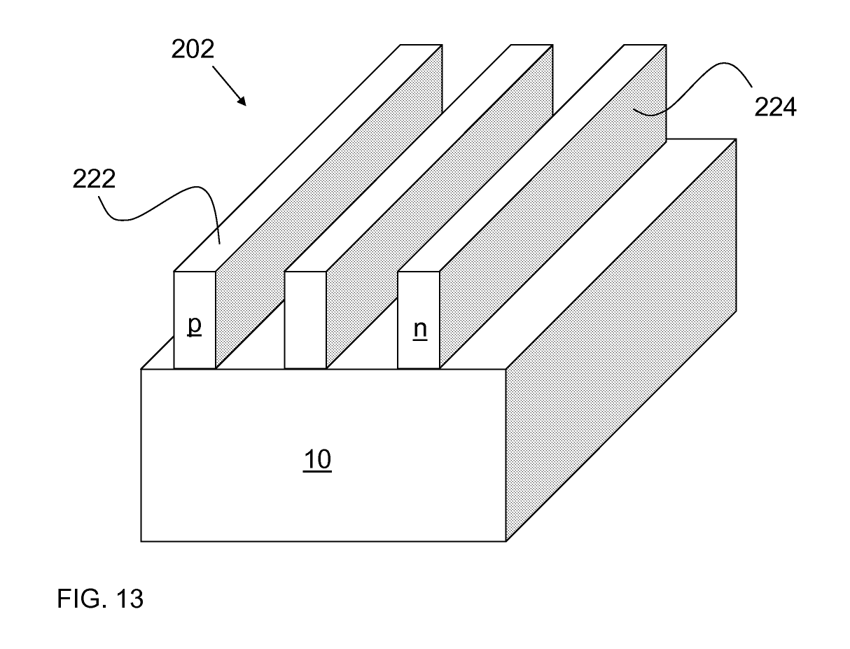

Turning to FIG. 13, after removal of the first stress layer 32 and second stress layer 34, a semiconductor structure 202 is formed. Semiconductor structure 202 may include substantially similar components as semiconductor structure 102. However, in one embodiment, semiconductor structure 202 may include distinctly doped fins (p-type 222 and n-type 224), which may later aid in forming a pFET region and nFET region of a fin-FET structure. Further, p-type fin 222 may include an imparted compressive stress, and n-type fin 224 may include an imparted tensile stress. In contrast to conventional methods, forming of semiconductor structure 202 including stressed fins (222, 224) is performed before forming of an MHK layer and a gate in a fin-FET structure (later formed from semiconductor structure 202). It is understood that forming of the MHK layer, the gate and other components in a fin-FET structure may be performed substantially similarly as described with reference to FIGS. 4-7. As such, repeated discussions of those processes are omitted.

In any case, it is understood that the methods described according to embodiments herein provide for amorphizing and inducing stress in semiconductor fins prior to forming of the MHK layer and the gate. In contrast to conventional methods, the methods described according to embodiments herein may provide for improved stress across the channel region of a fin-FET structure, particularly in portions of a fin (e.g., fins 20, 222, 224) underlying the MHK layer and gate region in a fin-FET structure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiments were chosen and described in order to best explain the principles of the disclosure and the practical application, and to enable others of ordinary skill in the art to understand the disclosure for various embodiments with various modifications as are suited to the particular use contemplated.

1. A method of forming a fin-shaped field effect transistor (fin-FET), the method comprising:
providing a partially amorphized fin overlying a substrate;
forming a stress layer over a portion of the partially amorphized fin;
annealing to impart stress in the partially amorphized fin to form a stressed fin;
removing the stress layer from over the portion of the stressed fin;
forming a metal high-dielectric constant (MHK) layer over the stressed fin after the removing of the stress layer; and
forming a gate over the MHK layer after the removing of the stress layer and the forming of the MHK layer.

2. The method of claim 1, wherein partially amorphized fin is formed by etching a semiconductor layer overlying the substrate to form a non-amorphized fin prior to being partially amorphized.

3. The method of claim 1, wherein the stress layer comprises a compressive stress nitride layer.

4. The method of claim 3, wherein the removing of the stress layer is performed using a hot phosphorous bath or reactive ion etching.

5. The method of claim 1, wherein the stress layer comprises a tensile stress nitride layer.

6. The method of claim 1, wherein the partially amorphized fin is ion implanted.

7. The method of claim 6, wherein the implanted ion includes germanium (Ge).

8. The method of claim 6, wherein the implanted ion includes carbon (C).

9. The method of claim 6, wherein said fin is a first fin, and the providing further includes providing a partially amorphized second fin overlying the substrate, the partially amorphized second fin including an ion implanted second fin with an ion species distinct from an ion species in the ion implanted first fin.

10. The method of claim 1, wherein the annealing is performed after the forming of the stress layer and before the forming of the MHK layer and the gate.

11-20. (canceled)

21. The method of claim 1, wherein the MHK layer has a dielectric constant value (k) greater than approximately 18.

22. The method of claim 21, wherein the forming of the MHK layer includes selectively depositing the MHK layer over the stressed fin after the removing of the stress layer.

23. The method of claim 22, wherein the forming of the gate over the MHK layer includes forming the gate over only the MHK layer such that the MHK layer separates the gate from the fin.
